(19) United States
(12) Patent Application Publication
(10) Pub. No.: US 2018/0032778 A1
(43) Pub. Date: Feb. 1, 2018

(54) DISPLAY WITH A TOUCH SENSOR

(71) Applicant: Microsoft Technology Licensing, LLC, Redmond, WA (US)

(72) Inventor: Jouko Lång, Lieto (FI)

(21) Appl. No.: 15/224,317

(22) Filed: Jul. 29, 2016

(51) Int. Cl. G06K 9/00; H01L 27/32

(52) U.S. Cl. CPC G06K 9/0002; G06K 9/0008; H01L 27/323; G06K 2009/0006

(57) ABSTRACT

A device, a display and a system are disclosed, all having a display with touch sensing capability. The display senses an object touching the surface of the display and emits light towards the touching object. The light reflects back from the object and travels back through the display to a light detector layer underneath the display stack. The light sensing layer is attached to the display stack with a transparent adhesive that maintains the fingerprint details detectable when the light travels back from the object. The light detector layer may replace the back layer of the display stack. The light detector layer may be applied in various devices having a touch sensing display. The light detector layer may be modular addition to displays in different applications that use identification.

### BACKGROUND

Biometric systems may be used to identity an individual automatically. Fingerprint sensing is one of the most widely deployed biometric sensing technologies providing reliable user authentication with low false acceptance rates (FAR) as well as low false rejection rates (FRR). Fingerprint sensing may be used to unlock a mobile device. The fingerprint may be sensed from the display of the mobile device, for example through an OLED display, wherein the fingerprint sensor and the display stack layers are integrated. Such arrangements may require proprietary display, wherein the display may be suitable for a specific purpose or device and thus the manufacturing cost and design requirements may rise too high for wider array of devices.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

A device, a display and a system are disclosed, all having a display with touch sensing capability. The display senses an object touching the surface of the display and emits light towards the area of the touching object. The light reflects back from the object and travels back through the display to a light detector layer underneath the display stack. The light detector layer has a resolution suitable for detecting features of a fingerprint from the reflected light.

The light sensing layer is attached to the display stack with a transparent adhesive that maintains the fingerprint details detectable when the light travels back from the object. The light detector layer may replace the back layer of the display stack. The light detector layer may be applied in various devices having a touch sensing display. The light detector layer may be a modular addition to displays in different applications that use identification.

Many of the attendant features will be more readily appreciated as they become better understood by reference to the following detailed description considered in connection with the accompanying drawings.

### DESCRIPTION OF THE DRAWINGS

The present description will be better understood from the following detailed description read in light of the accompanying drawings, wherein:

FIG. 1 illustrates a device according to an embodiment; and

FIG. 2 illustrates schematically a cross-sectional view of one embodiment of a display having a light detector layer.

Like reference numerals are used to designate like parts in the accompanying drawings.

### DETAILED DESCRIPTION

The detailed description provided below in connection with the appended drawings is intended as a description of the present embodiments and is not intended to represent the only forms in which the present embodiments may be constructed or utilized. However, the same or equivalent functions and sequences may be accomplished by different embodiments.

Although the present embodiments are described and illustrated herein as being implemented in a smartphone, the device described is provided as an example and not a limitation. As those skilled in the art will appreciate, the present embodiments are suitable for application in a variety of different types of mobile and/or hand-held apparatuses, e.g. in tablets, smart watches, laptops or gaming consoles or larger devices such as televisions or automotive applications. The fingerprint detection may be used in various applications and apparatuses having a display with touch sensors. The display may be a peripheral connected to a system, wherein at least a portion of the user interface is deployed in the display.

In one embodiment a finger is detected with a touch sensor integrated to the display. The RGB OLEDs of the display are illuminated within the finger area. The light reflected from the finger travels back through the display stack and is detected and recorded at an organic photodetector array behind the OLED stack. The organic photodetector array produces a high definition image, enabling features of the fingerprint to be detected and the person to be identified.

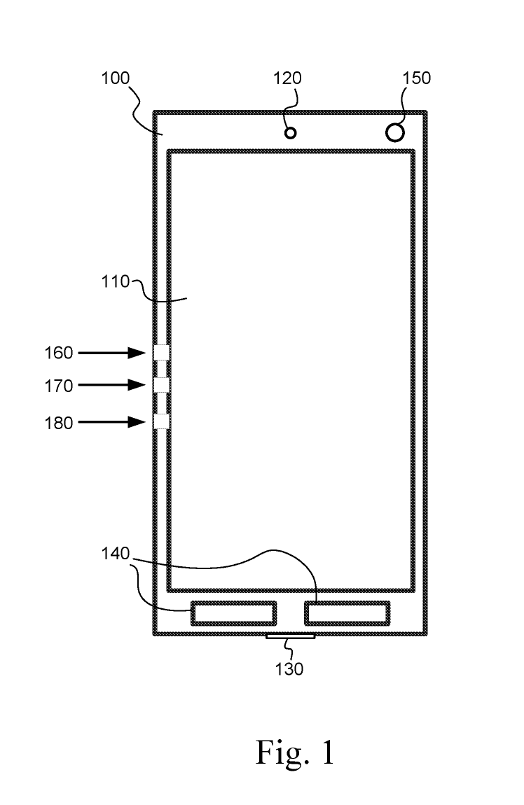

FIG. 1 illustrates a device according to an embodiment, wherein the device is a smartphone. The device comprises a body 100 comprising a display 110, a speaker 120, a microphone 130, keys 140 and a camera 150. The device comprises at least one processor 160 and at least one memory 170 including computer program code for one or more programs. The at least one memory 170 and the computer program code are configured, with the at least one processor 160, cause the device to perform at least the functionality described herein. The device comprises an object detection element 180 that may comprise features or functions of one or more components required for object detection. In one embodiment, the object detection element 180 is an integrated chip comprising a memory and a processor. In one embodiment the object detection element 180 comprises the functional chain of components and functions for controlling the display, such as the CPU, the memory or display management circuit or function. The system described hereinafter may comprise a portion of the device, its components and/or peripherals connected to the device.

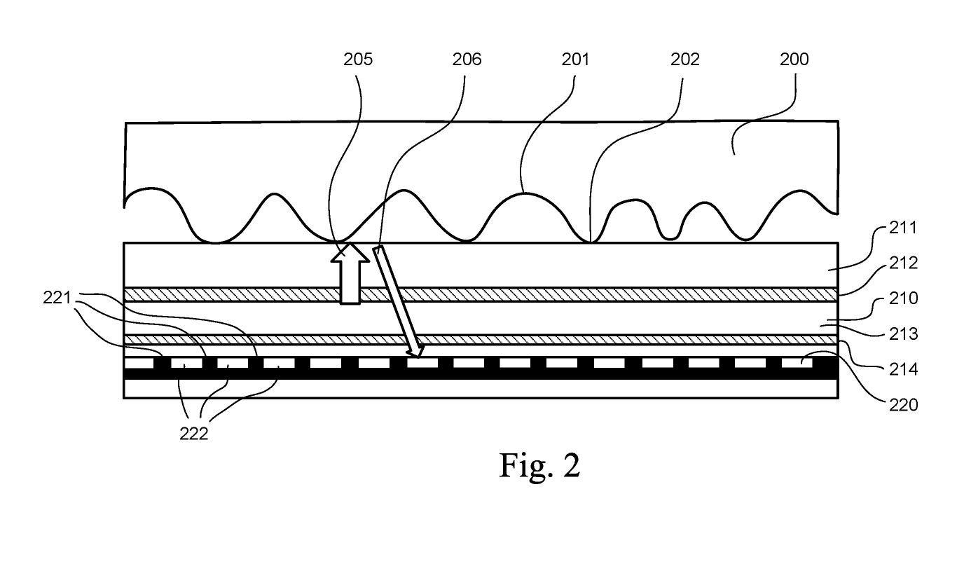

FIG. 2 illustrates schematically a cross-sectional view of one embodiment of a display having a light detector layer. In this context, directions such as “top”, “higher” or “up” relate to the visible side of the display having the window 211 and define a first side of the display; and “bottom”, “lower” or “down” relate to the side of the display stack 210 that is towards the internals of the device and define a second side of the display. The display may be part of a device, such as the smartphone as illustrated in FIG. 1. A display stack 210 comprises a display with all the hardware 213 for enabling a touch sensitive display. Examples of such hardware 213 in the display stack layer 210 comprises layers configured to detect a change in the capacitance of a portion of the display, for example a touch of a human finger. Examples of such layers are a common voltage layer, configured to comprise a single function, such as a VCOM layer for the display or a guard electrode layer. The display stack 210 also comprises conducting elements configured to carry a signal to a specified position in the display stack 210. On top of the display stack 210 is a display window 211 that may be attached to the display stack 211 with a transparent adhesive layer 212.

The display stack 210 comprises a plurality of light emitters configured to emit light as a display, wherein in one embodiment the light emitters are arranged as a layer of light emitters. The touch sensing elements 213 on the display stack 210 detect an object 200 being in contact with the display window 211. In one embodiment the object detection element 180 detects that the size and shape of the object 200 conforms a human finger and causes the display stack 210 to emit light 205 towards the object 200 placed in contact with the display window 211. In one embodiment the light 205 is emitted only in the area detected to have contact with the object 200 or a larger portion of the display stack may be configured to emit light. The light 205 may be emitted partially, in one embodiment the light 205 is emitted as a sweeping light having a limited number of pixels lit. Pixels are individual light emitters in the display stack 210. In one embodiment the number of pixels relates to the resolution of a human fingerprint.

In one embodiment the display stack 210 comprises an OLED display (OLED, Organic Light-Emitting Diode). The display stack 210 is at least partially transparent allowing light to travel through the display stack 210. In one embodiment the display stack 210 comprises a white OLED display or a wRGB OLED display having a white sub-pixel with the RGB pixels.

A detector layer 220 comprising a plurality of light receptors 221 is configured to receive a portion of light 206 reflected back from the object. The display stack 210 is configured to permit the portion of light 206 reflected back from the object to travel through the display stack 210 to the detector layer 220. A portion of the reflected light 206 may be blocked or absorbed by the internal non-transparent elements of the display stack 210. In one embodiment the light receptors comprise organic photodetector materials capable of reaching external quantum efficiencies of around 50% of the back reflected light 206. In one embodiment the light receptors comprise organic photodetector materials capable of reaching external quantum efficiencies of around 85% of the back reflected light 206. The efficiency of the organic photodetector materials enables detecting the rays of light 206 passing through the display stack 210. A second adhesive layer 214 attaches the detector layer 220 on a second side of the display, under the display stack 210. The adhesive layer 214, is optically transparent allowing rays of light to travel though the material. In one embodiment the adhesive layer 214 comprises transparent adhesive. In one embodiment the adhesive layer 214 is flexible when cured.

In one embodiment the OLED display stack 210 is semitransparent especially in the infrared region of the spectrum. The transparency of the display stack 210 may be enhanced when transparent anode/cathode OLED electrodes are used for the bottom electrodes and if e.g. oxide or carbon nanotube thin film transistors are used instead of low-temperature polycrystalline silicon. In one embodiment a backplane substrate is made of optical-grade polyimide.

In one embodiment the detector layer 220 is considered as a fingerprint sensor comprising organic photodetectors 221 and organic thin film transistors 222 (TFTs) for read out electronics. The organic photodetectors 221 are configured on a plastic film substrate. The detector layer 220 may cover, from beneath, the whole display stack 210. In one embodiment the TFT is a switch, allowing a current from the photodetectors, such as photodiodes, to an external amplifier configured to amplify the signal caused by the detected light. In one embodiment the organic photodetectors 221 and organic thin film transistors 222 are arranged into a three-transistor active pixel sensor layout, wherein one thin film transistor 222 is configured to amplify the signal received from the photodetector 221, one transistor is configured as a switch and one transistor as a pixel reset transistor.

In one embodiment of the device, the display or the system comprises a controller 180 configured to image the object 200 placed in contact with a first side of the display stack 210 based on light emitted by the display. The controller 180 detects the finger and illuminates the touched area of the display. In one embodiment the controller detects that the object is a human fingerprint using the information received from the touch sensor. The controller receives the imaging information from the detector layer 220. In one embodiment the controller 180 constructs one fingerprint image from multiple partial images. In one embodiment the controller 180 comprises a processor and a memory storing instructions that, when executed, control the operation of the device, the display or the system.

In one embodiment the display stack 210 emits light 205 in a portion indicating to the user a position on the display for the finger to be placed for detection and recognition. A human fingerprint comprises valleys 201 and ridges 202, wherein only ridges are in contact with the display window 211. The emitted light 205 may reflect in a different manner from the objects in contact with the display 211, for example total internal reflection (TIR) may not apply to those parts. Rays of light that touch parts of the outer surface 110 in contact with a ridge 202 of the fingerprint, do not experience TIR and exit to illuminate the ridge. Therefore portions of the fingerprint ridges 202 may be imaged with the rays of light not experiencing TIR and the position where the rays of light 206 reflect back towards the display stack 211 are in a different position than the light emitters. In one embodiment the light 206 reflected back from the is detected from the emitted light 205 passing through the display window 211, wherein portions of valleys 201 may reflect light back towards the display stack 210. In one embodiment the detector layer 220 relies on the frustrated total internal reflection (FTIR) phenomena in which the light 206 reflected from the finger 200 is altered due to changes in the conditions of the total internal reflection at the glass-air interface. The light is reflected at the valleys 201 of the finger 200 and randomly scattered/absorbed at the ridges 202. Thus the ridges 202 may appear darker when recorded with the detector layer 220.

The detector layer 220 is in one embodiment a flexible layer comprising a plastic substrate. The flexible detector layer 220 is compatible with flexible display system. In one embodiment the detector layer 220 comprises a plastic substrate, wherein the organic photodetectors 221 and the thin film transistors 222 are printed for example by low temperature roll-to-roll method. Moreover, fingerprint sensors made of plastic have similar optical performances to conventional optical fingerprint sensors such as sensitivity, linearity, and low noise, but without the need for expensive and bulky optics. In one embodiment the plastic optical fingerprint sensors on the detector layer 220 comprise organic TFT layer 222 on plastic substrate accompanied by printed organic photodetectors 221. In one embodiment the overall detector layer thickness is less than 300 μm. The manufacturing methods allow the detector layer 220 to be scaled to different display sizes, for example to the size of the smartphone display 110. Large area fingerprint sensors may allow more information to be collected—which may provide better performance on two key metrics compared to smaller sensor areas—higher security and lower false rejection rate.

The structure may allow secure authentication with antispoofing—for example if RGB colors are used for illumination—for mobile form factors. It may also enable the usage of whole display screen as a fingerprint sensor. The detector layer integration may be easy and economical to integrate in various products since the structure may be implemented without modifying the display structure. The overall structure may be kept thin since the detector layer 220 may be used to replace a traditional black tape behind the OLED display.

One aspect discloses a device comprising: a display stack comprising a display; the display comprising a plurality of light emitters configured to emit light towards an object placed in contact with a first side of the display; a detector layer comprising a plurality of light receptors configured to receive a portion of light reflected back from the object; an adhesive layer attaching the detector layer to the display stack on a second side of the display; wherein the display stack is configured to permit a portion of light reflected back from the object to travel through the display stack to the detector layer. In an embodiment the display is an organic light-emitting diode display. In an embodiment the device comprises a controller configured to image the object placed in contact with a first side of the display stack based on light emitted by the display. In an embodiment the controller comprises a processor and a memory storing instructions that, when executed, control the operation of the device. In an embodiment the display stack comprises a touch sensor. In an embodiment the adhesive is an optical adhesive configured to allow light to pass through the adhesive layer to the detector layer. In an embodiment the object is a human finger and the detector is configured to detect a human fingerprint.

Alternatively or in addition, one aspect discloses a device comprising: a display stack comprising a display; the display comprising a means for emitting light towards an object placed in contact with a first side of the display; a detector layer comprising a means for receiving a portion of light reflected back from the object; an adhesive layer attaching the detector layer to the display stack on a second side of the display; wherein the display stack is partially transparent permitting the portion of light reflected back from the object to travel through the display stack to the detector layer. In an embodiment the display is an organic light-emitting diode display. In an embodiment the device comprises a means for imaging the object placed in contact with a first side of the display stack based on light emitted by the display. In an embodiment the means for imaging comprises a processor and a memory storing instructions that, when executed, control the operation of the device. In an embodiment the display stack comprises a touch sensor. In an embodiment the adhesive is an optical adhesive configured to allow light to pass through the adhesive layer to the detector layer. In an embodiment the object is a human finger and the device comprises means for detecting a human fingerprint.

Alternatively or in addition, one aspect discloses a display, comprising: a plurality of light emitters configured to display an image and to emit light towards a human finger placed in contact with a first side of the display; a plurality of touch sensors configured to detect the contact of the human finger with one side of the display; a display stack comprising layers of said plurality of light emitters and said plurality of touch sensors; a detector layer comprising a plurality of light receptors configured to receive a portion of light reflected back from the human finger and to detect a ridge of the human finger; and an adhesive layer attaching the detector layer to the display stack on the second side of the display; wherein the display stack is transparent, allowing the portion of light reflected back from the human finger to travel through the display stack to the detector layer. In an embodiment the plurality of light emitters are organic light-emitting diodes. In an embodiment the display comprises a controller configured to image the ridge of the human fingerprint placed in contact with the first side of the display. In an embodiment the adhesive is an optical adhesive configured to allow light to pass through the adhesive layer to the detector layer. In an embodiment the controller comprises a processor and a memory storing instructions that, when executed, control the operation of the device. In an embodiment the display stack comprises a touch sensor.

Alternatively or in addition, one aspect discloses a system, comprising: a display stack comprising a display; the display comprising a plurality of light emitters configured to emit light towards an object placed in contact with a first side of the display; a detector layer comprising a plurality of light receptors configured to receive a portion of light reflected back from the object; and an adhesive layer attaching the detector layer to the display stack on a second side of the display; wherein the display stack is configured to permit the portion of light reflected back from the object to travel through the display stack to the detector layer. In one embodiment the display is an organic light-emitting diode display. In one embodiment the system comprises a controller configured to image the object placed in contact with a first side of the display stack based on light emitted by the display. In one embodiment the controller comprises a processor and a memory storing instructions that, when executed, control the operation of the device. In one embodiment the display stack comprises a touch sensor. In one embodiment the adhesive is an optical adhesive configured to allow light to pass through the adhesive layer to the detector layer. In one embodiment the object is a human finger and the detector is configured to detect a human fingerprint.

Alternatively, or in addition, the functionality described herein can be performed, at least in part, by one or more hardware logic components. For example, and without limitation, illustrative types of hardware logic components that can be used include Field-programmable Gate Arrays (FPGAs), Program-specific Integrated Circuits (ASICs), Program-specific Standard Products (ASSPs), System-on-a-chip systems (SOCs), Complex Programmable Logic Devices (CPLDs), Graphics Processing Units (GPUs). For example, some or all of the display driver element functionality may be performed by one or more hardware logic components.

An embodiment, of the device, display or a system described hereinbefore is a computing-based device comprising one or more processors which may be microprocessors, controllers or any other suitable type of processors for processing computer executable instructions to control the operation of the device in order to control one or more sensors, receive sensor data and use the sensor data. Platform software comprising an operating system or any other suitable platform software may be provided at the computing-based device to enable application software to be executed on the device.

The computer executable instructions may be provided using any computer-readable media that is accessible by computing based device. Computer-readable media may include, for example, computer storage media such as memory and communications media. Computer storage media, such as memory, includes volatile and non-volatile, removable and non-removable media implemented in any method or technology for storage of information such as computer readable instructions, data structures, program modules or the like. Computer storage media includes, but is not limited to, RAM, ROM, EPROM, EEPROM, flash memory or other memory technology, CD-ROM, digital versatile disks (DVD) or other optical storage, magnetic cassettes, magnetic tape, magnetic disk storage or other magnetic storage devices, or any other non-transmission medium that can be used to store information for access by a computing device. In contrast, communication media may embody computer readable instructions, data structures, program modules, or in a modulated data signal, such as a carrier wave, or other transport mechanism. As defined herein, computer storage media does not include communication media. Therefore, a computer storage medium should not be interpreted to be a propagating signal per se. Although the computer storage media is shown within the computing-based device it will be appreciated that the storage may be distributed or located remotely and accessed via a network or other communication link, for example by using communication interface.

The computing-based device may comprise an input/output controller arranged to output display information to a display device which may be separate from or integral to the computing-based device. The display information may provide a graphical user interface, for example, to display hand gestures tracked by the device using the sensor input or for other display purposes. The input/output controller is also arranged to receive and process input from one or more devices, such as a user input device (e.g. a mouse, keyboard, camera, microphone or other sensor). In some embodiments, the user input device may detect voice input, user gestures or other user actions and may provide a natural user interface (NUI). This user input may be used to configure the device for a particular user. In an embodiment the display device may also act as the user input device. The input/output controller may also output data to devices other than the display device, e.g. a locally connected printing device.

The term ‘computer’ or ‘computing-based device’ is used herein to refer to any device with processing capability such that it can execute instructions. Those skilled in the art will realize that such processing capabilities are incorporated into many different devices and therefore the terms ‘computer’ and ‘computing-based device’ each include PCs, servers, mobile telephones (including smart phones), tablet computers, set-top boxes, media players, games consoles, personal digital assistants and many other devices.

The methods described herein may be performed by software in machine readable form on a tangible storage medium e.g. in the form of a computer program comprising computer program code means adapted to perform all the steps of any of the methods described herein when the program is run on a computer and where the computer program may be embodied on a computer readable medium. The software can be suitable for execution on a parallel processor or a serial processor such that the method steps may be carried out in any suitable order, or simultaneously.

This acknowledges that software can be a valuable, separately tradable commodity. It is intended to encompass software, which runs on or controls “dumb” or standard hardware, to carry out the desired functions. It is also intended to encompass software which “describes” or defines the configuration of hardware, such as HDL (hardware description language) software, as is used for designing silicon chips, or for configuring universal programmable chips, to carry out desired functions.

Those skilled in the art will realize that storage devices utilized to store program instructions can be distributed across a network. For example, a remote computer may store an example of the process described as software. A local or terminal computer may access the remote computer and download a part or all of the software to run the program. Alternatively, the local computer may download pieces of the software as needed, or execute some software instructions at the local terminal and some at the remote computer (or computer network).

Any range or device value given herein may be extended or altered without losing the effect sought.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

In the above description, some component, device, module, unit, or element “being configured to” operate in a specific manner or to carry out specific operations, or carrying out such operations when in use, refers to that component, device, module, unit, or element comprising, or itself serving as, “means for” operating in that manner or carrying out those operations.

For example the display comprising a plurality of light emitters and being configured to emit light towards an object placed in contact with a first side of the display comprises, or serves as, means for emitting light to an object placed in contact with a first side of the display. As another example, a detector layer comprising a plurality of light receptors being configured to receive a portion of light reflected back from the object comprises, or serves as, means for receiving a portion of light reflected back from the object.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item refers to one or more of those items.

The term ‘comprising’ is used herein to mean including the method blocks or elements identified, but that such blocks or elements do not comprise an exclusive list and a method or apparatus may contain additional blocks or elements.

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from the spirit or scope of this specification.

1. A device, comprising:
a display stack comprising a display;
the display comprising a plurality of light emitters configured to emit light towards an object placed in contact with a first side of the display;
a detector layer comprising a plurality of light receptors configured to receive a portion of light reflected back from the object; and
an adhesive layer attaching the detector layer to the display stack on a second side of the display; wherein
the display stack is configured to permit a portion of light reflected back from the object to travel through the display stack to the detector layer.

2. A device according to claim 1, wherein the display is an organic light-emitting diode display.

3. A device according to claim 1, comprising a controller configured to image the object placed in contact with a first side of the display stack based on light emitted by the display.

4. A device according to claim 3, wherein the controller comprises a processor and a memory storing instructions that, when executed, control the operation of the device.

5. A device according to claim 1, wherein the display stack comprises a touch sensor.

6. A device according to claim 1, wherein the adhesive is an optical adhesive configured to allow light to pass through the adhesive layer to the detector layer.

7. A device according to claim 1, wherein the object is a human finger and the detector is configured to detect a human fingerprint.

8. A display, comprising:
a plurality of light emitters configured to display an image and to emit light towards a human finger placed in contact with a first side of the display;
a plurality of touch sensors configured to detect the contact of the human finger with one side of the display;
a display stack comprising layers of said plurality of light emitters and said plurality of touch sensors;
a detector layer comprising a plurality of light receptors configured to receive a portion of light reflected back from the human finger and to detect a ridge of the human finger; and
an adhesive layer attaching the detector layer to the display stack on the second side of the display; wherein
the display stack is transparent, allowing the portion of light reflected back from the human finger to travel through the display stack to the detector layer.

9. A display according to claim 8, wherein the plurality of light emitters are organic light-emitting diodes.

10. A display according to claim 8, comprising a controller configured to image the ridge of the human fingerprint placed in contact with the first side of the display.

11. A display according to claim 10, the controller comprising a processor and a memory storing instructions that, when executed, control the operation of the device.

12. A display according to claim 8, wherein the display stack comprises a touch sensor.

13. A display according to claim 8, wherein the adhesive is an optical adhesive configured to allow light to pass through the adhesive layer to the detector layer.

14. A system, comprising:
a display stack comprising a display;
the display comprising a plurality of light emitters configured to emit light towards an object placed in contact with a first side of the display;
a detector layer comprising a plurality of light receptors configured to receive a portion of light reflected back from the object;
an adhesive layer attaching the detector layer to the display stack on a second side of the display; and wherein
the display stack is configured to permit a portion of light reflected back from the object to travel through the display stack to the detector layer.

15. A system according to claim 14, wherein the display is an organic light-emitting diode display.

16. A system according to claim 14, comprising a controller configured to image the object placed in contact with a first side of the display stack based on light emitted by the display.

17. A system according to claim 16, wherein the controller comprises a processor and a memory storing instructions that, when executed, control the operation of the device.

18. A system according to claim 14, wherein the display stack comprises a touch sensor.

19. A system according to claim 14, wherein the adhesive is an optical adhesive configured to allow light to pass through the adhesive layer to the detector layer.

20. A system according to claim 14, wherein the object is a human finger and the detector is configured to detect a human fingerprint.
